(19) United States
(12) Patent Application Publication
(10) Pub. No.: US 2010/0244901 A1
(43) Pub. Date: Sep. 30, 2010

(54) CLOCK SWITCHING CIRCUIT, INTEGRATED CIRCUIT DEVICE AND ELECTRONIC APPARATUS

(75) Inventor: Keisuke HASHIMOTO, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/726,595

(22) Filed: Mar. 18, 2010

(30) Foreign Application Priority Data
Mar. 25, 2009 (JP) 2009-073918

(51) Int. Cl. H03K 19/096

(52) U.S. Cl. 326/93; 326/52

(57) ABSTRACT

A clock switching circuit includes: a selector that selects one of a plurality of clocks based on a select signal and outputs the clock selected as a selected clock; a mask circuit that masks the selected clock based on a mask signal and outputs the selected clock masked as an output clock; and a mask signal generation circuit that generates the mask signal and the select signal, the mask signal generation circuit switches a signal level of the select signal after causing the mask signal to be active, and causes the mask signal to be inactive on condition that a change is detected in the signal level of the selected clock after the signal level of the select signal has been switched.

The present application claims a priority based on Japanese Patent Application No. 2009-073918 filed on Mar. 25, 2009, the contents of which are incorporated herein by reference.

### BACKGROUND

1. Technical Field

The present invention relates to clock switching circuits, integrated circuit devices and electronic apparatuses.

2. Related Art

Generally, an integrated circuit device such as a microcomputer switches among a plurality of clocks with different frequencies and uses them as system clocks (internal clocks). For example, an integrated circuit device may be provided with a crystal oscillator to obtain a highly accurate frequency, a ceramic oscillator for operating the microcomputer at high frequencies, and the like, wherein appropriate ones of the clocks generated by these oscillators are selected and supplied to the core circuit (a CPU or the like) of the microcomputer. Accordingly, an integrated circuit device such as a microcomputer has the task of switching a plurality of clocks with one another.

For example, when clocks are switched, glitches (undesired pulses) may be generated in output clocks depending on phase relation among the clocks to be switched. If a clock having a glitch is inputted in the core circuit, the core circuit may possibly malfunction. Therefore, clocks need to be switched without generating a glitch. Also there may be certain situations where clocks with various frequencies may be used as system clocks, or multiple clocks of three or more may be switched and used. For this reason, it is necessary to provide a capability of switching clocks at certain frequency ratios with one another and also a capability of switching three or more clocks with one another.

In this connection, Japanese Laid-open Patent Application 09-098161 describes a method of switching clocks of two systems and preventing a glitch and a phase skip from being generated when switching the clocks.

### SUMMARY

In accordance with some embodiments of the invention, it is possible to provide clock switching circuits, integrated circuit devices and electronic apparatuses, which are capable of switching a plurality of clocks with one another.

An embodiment of the invention pertains to a clock switching circuit having: a selector that selects one of a plurality of clocks based on a select signal and outputs the clock selected as a selected clock; a mask circuit that masks the selected clock based on a mask signal and outputs the selected clock masked as an output clock; and a mask signal generation circuit that generates the mask signal and the select signal, wherein the mask signal generation circuit switches a signal level of the select signal after causing the mask signal to be active, and causes the mask signal to be inactive on condition that a change is detected in the signal level of the selected clock after the signal level of the select signal has been switched.

According to an aspect of the embodiment of the invention, the mask signal generation circuit switches the signal level of a select signal after making a mask signal active, the selector selects one of a plurality of clocks based on the select signal and outputs the same as a selected clock, the mask signal generation circuit makes the mask signal inactive on condition that a change is detected in the signal level of the selected clock after the signal level of the select signal has been switched, and the mask circuit masks the selected clock based on a mask signal and outputs the same as an output clock.

In this manner, according to one aspect of the embodiment of the invention, the signal level of a select signal is switched after a mask signal has been made active. By this, during the period in which the selected clock is masked based on the mask signal, the clock can be switched based on the select signal. Also, according to another aspect of the embodiment of the invention, the mask signal is made inactive on condition that a change is detected in the signal level of the selected clock after the signal level of the select signal has been switched. Therefore, the selected clock can be masked until a change is detected in the signal level of the selected clock after the signal level of the select signal has been switched. For example, even when a glitch at H level is generated in the selected clock at the time of clock switching, the glitch can be masked by causing the mask signal to be inactive upon detecting a falling edge of the glitch. In this manner, according to the present embodiment, a plurality of clocks can be switched without generating a glitch in output clocks.

In accordance with an embodiment of the invention, the mask signal generation circuit may make the mask signal active through sampling a clock switching signal based on the output clock or a delay clock of the output clock.

According to the embodiment of the invention described above, the mask signal can be made active through sampling a clock switching signal based on the output clock or a delay clock of the output clock. Accordingly, even when one of the plural clocks has been selected prior to clock switching, the mask signal can be made active. Also, as described above, by causing the mask signal to be inactive upon detecting a change in the signal level of the selected clock after the signal level of the select signal has been switched, the mask signal can be made inactive even when any one of the plural clocks is selected after clock switching. In this manner, the mask signal can be generated when switching between any clocks among a plurality of clocks. With this, even when three or more clocks, as a plurality of clocks, are switched, the clocks can be switched without generating a glitch.

In accordance with another embodiment of the invention, the mask signal generation circuit may output the select signal based on a delay signal of a signal that is generated through sampling the clock switching signal based on the output clock or a delay clock of the output clock.

With this, the timing to switch the signal level of the select signal can be delayed with respect to the timing at which the mask signal is made active. Accordingly, during the period in which the selected clock is masked, the clock can be switched.

In accordance with still another embodiment of the invention, the mask signal generation circuit may include a first flip-flop circuit that samples the clock switching signal based on the output clock or a delay clock of the output clock and outputs a first output signal, a second flip-flop circuit that samples the first output signal based on the selected clock and outputs a second output signal, and an exclusive OR circuit that obtains an exclusive OR of the first output signal and the second output signal and outputs the mask signal, wherein the selector receives the select signal based on the first output signal and selects one of a first clock and a second clock among the plurality of clocks.

According to the embodiment of the invention described above, by the inclusion of the first flip-flop circuit, the mask signal can be made active through sampling the clock switching signal based on an output clock or a delay clock of the output clock. Also, as the second flip-flop circuit samples the first output signal based on the selected clock, the mask signal can be made inactive on condition that a change in the signal level of the selected clock is detected. Accordingly, a clock switching circuit that switches between a first clock and a second clock without generating a glitch.

Further, in accordance with yet another embodiment of the invention, the mask signal generation circuit may include a delay circuit that receives the first output signal from the first flip-flop circuit and outputs the select signal.

With this, it is possible to delay the first output signal that is a signal generated through sampling a clock switching signal based on an output clock or a delay clock of the output clock, and to output a select signal based on the delayed first output signal.

In accordance with another embodiment of the invention, the mask signal generation circuit may include a first flip-flop circuit that samples the clock switching signal based on the output clock or a delay clock of the output clock and outputs a first output signal, a second flip-flop circuit that samples the first output signal based on the selected clock and outputs a second output signal, a first exclusive OR circuit that obtains an exclusive OR of the first output signal and the second output signal and outputs a first mask signal, a third flip-flop circuit that samples the clock switching signal based on the output clock or a delay clock of the output clock and outputs a third output signal, a fourth flip-flop circuit that samples the third output signal based on the selected clock and outputs a fourth output signal, a second exclusive OR circuit that obtains an exclusive OR of the third output signal and the fourth output signal and outputs a second mask signal, and a mask signal output circuit that outputs the mask signal based on the first mask signal and the second mask signal, wherein the selector may receive the select signal based on the first output signal and the third output signal and may select any one of a first clock through a fourth clock among the plurality of clocks.

According to an aspect of the embodiment of the invention described above, by the inclusion of the first and third flip-flop circuits, the mask signal can be made active through sampling the clock switching signal based on the output clock or a delay clock of the output clock. According to another aspect of the embodiment of the invention, the second and fourth flip-flop circuits sample the first and third output signals based on the selected clock, and the mask signal can be made inactive on condition that a change is detected in the signal level of the selected clock. In this manner, it is possible to realize a clock switching circuit that switches among the first through fourth clocks without generating a glitch.

Also, in accordance with another embodiment of the invention, the mask signal generation circuit may include a delay circuit that outputs the select signal upon receiving the first output signal from the first flip-flop circuit and the third output signal from the third flip-flop circuit.

With this, it is possible to delay the first and third output signals that are signals generated through sampling a clock switching signal based on an output clock or a delay signal of the output clock, and to output a select signal based on the delayed first and third output signals.

Furthermore, another embodiment of the invention pertains to an integrated circuit device including one of the clock switching circuits described above.

Moreover, still another embodiment of the invention pertains to an electronic apparatus including the integrated circuit device described above.

### BRIEF DESCRIPTION OF THE DRAWINGS

FIG. 1 shows an example for comparison with an embodiment of the invention.

FIG. 2 shows an example of signal waveforms of the comparison example.

FIG. 3 shows a composition example of a clock switching circuit in accordance with an embodiment of the invention.

FIG. 4 shows an example of signal waveforms of the clock switching circuit according to the composition example.

FIG. 5 shows an example of signal waveforms of the clock switching circuit according to the composition example.

FIG. 6 shows a first detailed composition example of a clock switching circuit in accordance with the present embodiment.

FIG. 7 shows an example of signal waveforms of the clock switching circuit according to the first detailed composition example.

FIG. 8 shows a second detailed composition example of a clock switching circuit in accordance with the present embodiment.

FIG. 9 shows an example of signal waveforms of the clock switching circuit according to the second detailed composition example.

FIG. 10 shows a composition example of an integrated circuit device.

FIG. 11 shows a composition example of an electronic apparatus.

### DESCRIPTION OF EXEMPLARY EMBODIMENTS

Preferred embodiments of the invention are described in detail below. It is noted that the embodiments described below should not unduly limit the content of the invention recited in the scope of the claimed invention, and all of the compositions to be described in the embodiments may not necessarily be indispensable as means for solution provided by the invention.

### 1. Comparison Example

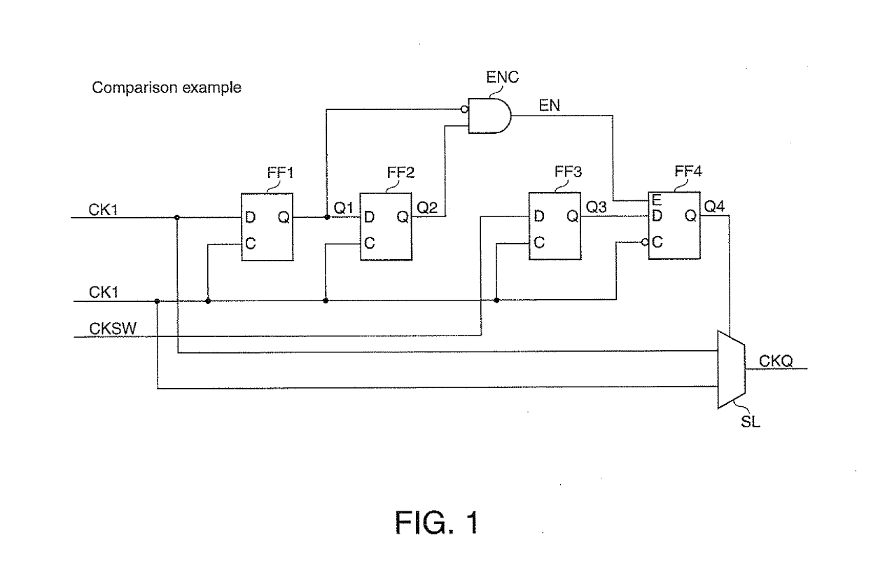

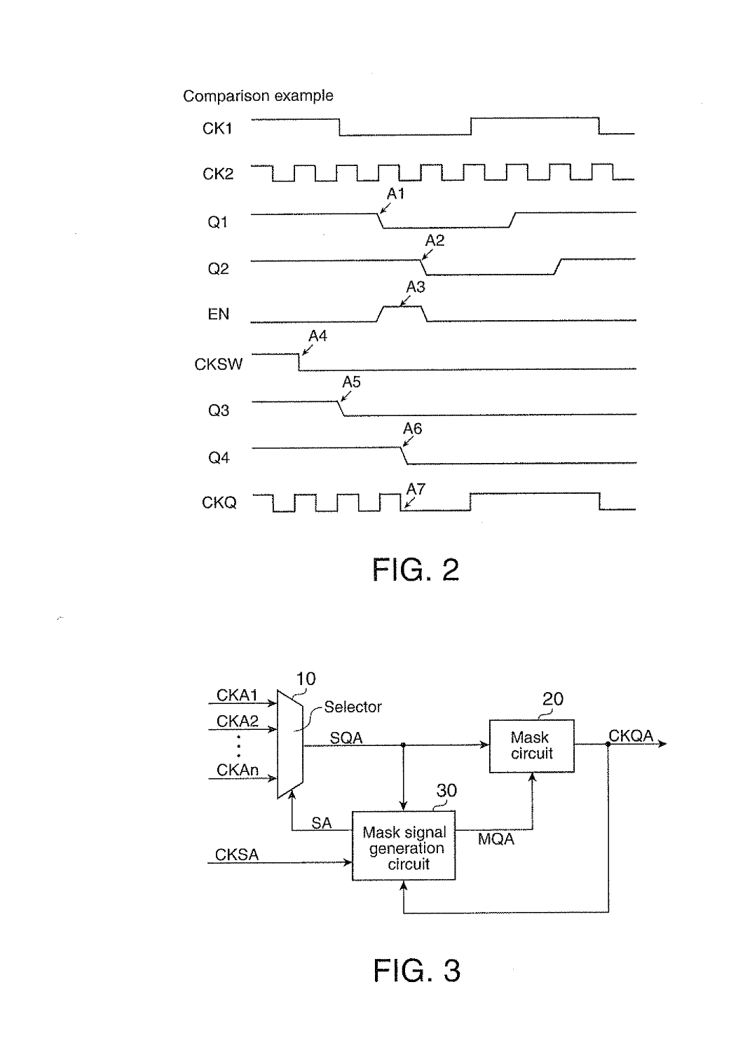

Referring to FIG. 1 and FIG. 2, an example for comparison with the present embodiment is described. FIG. 1 shows a clock switching circuit according to the comparison example. The clock switching circuit of the comparison example includes flip-flop circuits FF1-FF4, an enable signal generation circuit ENC, and a selector SL. The clock switching circuit is a circuit that switches among a clock CK1 and a clock CK2 with a frequency higher than that of the clock CK1.

Specifically, the FF1 latches (retains) the CK1 at a rising of the CK2, and outputs an output signal Q1. The FF2 latches the output signal Q1 from the FF1 at a rising edge of the CK2, and outputs an output signal Q2. The ENC sets an enable signal at H level when the Q1 is at L level and the Q2 is at H level. The FF3 latches a clock switching signal CKSW from a CPU (central processing unit) or the like at a rising edge of the CK2, and outputs an output signal Q3. The FF4 latches the Q3 at a falling edge of the CK2 when the EN is at H level, and outputs an output signal Q4. The SL selects the CK1 when the Q4 is at L level, and selects the CK2 when the Q4 is at H level, and outputs the selected clock as an output clock CKQ.

FIG. 2 shows an example of signal waveforms of the clock switching circuit according to the comparison example. FIG. 2 shows an example of signal waveforms in the case of switching the output clock CKQ from the CK2 to the CK1. As indicated at A1 of FIG. 2, the CK1 is latched at a rising edge of the CK2, and the Q1 is changed from H level to L level. As indicated at A2, the Q1 is latched at a rising edge of the CK2, and the Q2 is changed from H level to L level. As indicated by A3, during the period in which the Q1 is at L level and the Q2 is at H level, the EN is set to H level. As indicated at A4, the clock switching signal CKSW is changed from H level to L level. As indicated at A5, the CKSW is latched at a rising edge of the CK2, and the Q3 is changed from H level to L level. As indicated at AG, during the period in which the EN is at H level, the Q3 is latched at a falling edge of the CK2, and the Q4 is changed from H level to L level. Then, as indicated at A7, the output clock CKQ is switched from the CK2 to the CK1. In this manner, when the CK1 and the CK2 are both at L level, switching among the CK1 and the CK2 is conducted other, whereby the clocks can be switched without generating a glitch (an undesired pulse, a short spike or a hazard).

However, the clock switching circuit according to the comparison example samples the clock CK1 with the clock CK2. For this reason, the clock CK2 must have a frequency higher than that of the clock CK1, and the clock CK2 and the clock CK1 need to be in a frequency ratio of 2 or higher. Furthermore, although it is possible to switch among two clocks, it is difficult to cope with switching among three or more clocks.

### 2. Clock Switching Circuit

### 2.1. Composition Example

FIG. 3 shows a composition example of a clock switching circuit in accordance with an embodiment of the invention. The clock switching circuit shown in FIG. 3 includes a selector 10 (a selection circuit), a mask circuit 20, and a mask signal generation circuit 30 (a control circuit in a broad sense). The clock switching circuit is a circuit that switches among a plurality of clocks with desired frequency ratios and outputs the same without generating a glitch.

The selector 10 receives first-n-th clocks CKA1-CKAn (a plurality of clocks where n is a natural number of 2 or more) and a select signal SA (a clock selection signal) from the mask signal generation circuit 30, and outputs a selected clock SQA. More specifically, the selector 10 selects one of the clocks CKA1-CKAn based on the select signal SA, and outputs the selected clock as a selected clock SQA, For example, upon receiving the SA with a single bit or multiple bits, the selector 10 selects and outputs one of the clocks corresponding to the value of the SA. A clock generated by a clock generation circuit is inputted in the selector 10. For example, a clock generated by an oscillation circuit that uses a solid oscillator such as a crystal vibrator, a ceramic oscillator and the like, a clock generated by a built-in oscillation circuit such as a ring oscillator, a clock generated by a PLL (phase-locked loop) or the like may be inputted in the selector 10.

The mask circuit 20 receives a selection clock SQA, and outputs an output clock CKQA. More specifically, the mask circuit 20 masks the selection clock SQA based on a mask signal MQA from the mask signal generation circuit 30, and outputs the selection clock SQA after having been masked as an output clock CKQA. In other words, during the period in which the MQA is inactive (a first logical level in a broad sense), the mask circuit 20 outputs the SQA (or a clock obtained by inverting or delaying the SQA) as the CKQA. Also, in the period in which the MQA is active (a second logical level in a broad sense), the mask circuit 20 outputs the CKQA that is fixed at L level or H level thereby masking the MQA.

Upon receiving a clock switching signal CKSA, the output clock CKQA from the mask circuit 20 and the selected clock SQA from the selector 10, the mask signal generation circuit 30 outputs a mask signal MQA and a select signal SA. Specifically, when the signal level of the clock switching signal CKSA is changed, the mask signal generation circuit 30 causes the mask signal MQA to be active based on the output clock CKQA. Then, the mask signal generation circuit 30 switches the signal level of the select signal SA during the period in which the mask signal MQA is active, and causes the mask signal MQA to be inactive based on the selection clock SQA. For example, the mask signal generation circuit 30 samples the CKSA at a rising edge or a falling edge of the CKQA (or a delay clock of the CKQA), and causes the MQA to be active when there is a change in the signal level of the signal generated through sampling. Then the mask signal generation circuit 30 outputs the SA based on a delay signal of the signal generated through sampling the CKSA, thereby switching the signal level of the SA. After the SQA has been switched based on the SA, and upon detecting a rising edge or a falling edge (a change in the signal level) of the SQA, the mask signal generation circuit 30 causes the MQA to be inactive. It is noted that the clock switching signal CKSA can be supplied from a CPU inside the microcomputer (an integrated circuit device), or from a setting register at which register values can be set from an external host controller.

### 2.2. Operation Example

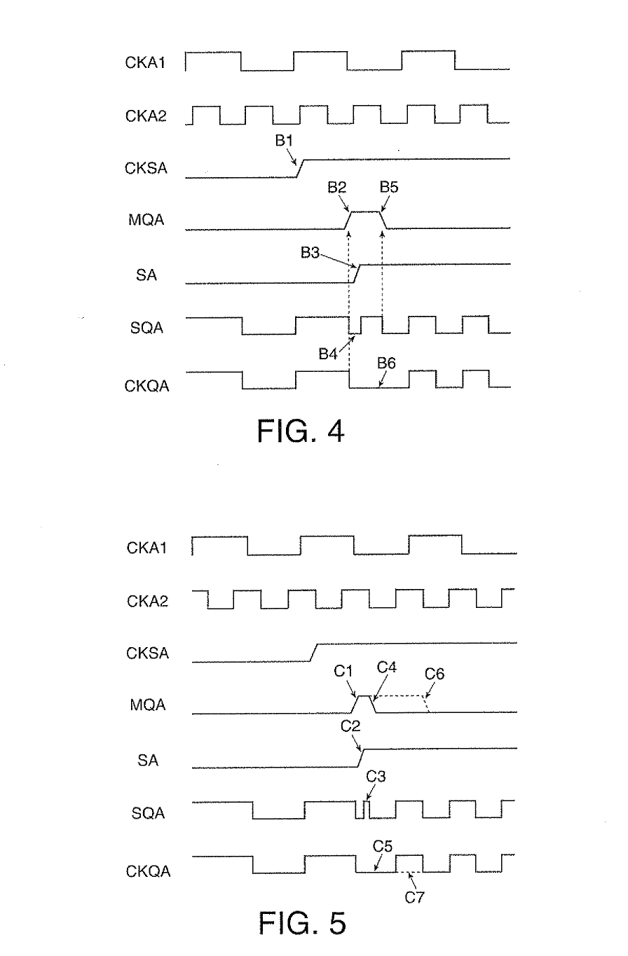

FIG. 4 shows an example of signal waveforms of the clock switching circuit according to the present embodiment. FIG. 4 shows an example of signal waveforms when clocks CKA1 and CKA2 among a plurality of clocks CKA1-CKAn are mutually switched. It is noted however that, according to the invention, any desired clocks among the clocks CKA1-CKAn can be switched with one another.

As indicated at B1 of FIG. 4, the CKSA is changed from L level to H level (or H level to L level), and as indicated at B2, the MQA is changed from L level to H level at a falling edge (a changing edge from H level to L level) of the CKQA. As indicated at B3, the SA is changed from L level to H level (or H level to L level) after the MQA has been changed to H level. As indicated at B4, the clock outputted as the SQA is switched from the CKA1 to CKA2. As indicated at B5, the MQA is changed from H level to L level at a falling edge of the SQA. As indicated at B6, during the period in which the MQA is at H level, the CKQA at L level is outputted. During the period in which the MQA is at L level, the SQA is outputted as the CKQA.

The example described with reference to FIG. 4 illustrates a case of masking a clock pulse at H level at the time of switching the SQA through causing the MQA to be active at a falling edge of the CKQA and causing the MQA to be inactive at a falling edge of the SQA. However, in accordance with the invention, it is also possible to mask a clock pulse at L level at the time of switching the SQA through causing the MQA to be active at a rising edge of the CKQA and causing the MQA to be inactive at a rising edge of the SQA.

In the example in FIG. 4, the active state of the MQA is described as H level, and the inactive state as L level. However, in the invention, the active state of the MQA can be L level, and the inactive state thereof can be H level.

In an integrated circuit device that switches among plural clocks and uses them, a glitch that may be generated in a clock at the time of switching clocks would cause a malfunction of a circuit to which the clock is supplied. Therefore it is necessary to switch among multiple clocks without generating a glitch.

In this respect, in accordance with the present embodiment, the mask signal generation circuit 30 makes the mask signal MQA active and then switches the signal level of the select signal SA, the selector 10 selects one of the clocks CKA1-CKAn based on the select signal SA to switch the selected clock SQA, the mask signal generation circuit 30 causes the mask signal MQA to be inactive on condition that a change is detected in the signal level of the selected clock SQA after the selected clock SQA has been switched, and the mask circuit 20 masks the selected clock SQA based on the mask signal MQA and outputs the output clock CKQA.

According to the present embodiment, the signal level of the select signal SA is changed after the mask signal MQA has been made active. With this, during the period in which the output clock CKQA is masked, one of the clocks CKA1-CKAn is selected, whereby the selected clock SQA can be switched. Also, in accordance with the present embodiment, the mask signal MQA is made inactive on condition that a change is detected in the signal level of the selected clock SQA after the selected clock SQA has been switched. With this, a fractional clock pulse that may be generated at the time of switching the selected clock SQA can be masked. This makes it possible to switch among plural clocks without generating a glitch.

The above feature is more concretely described with reference to FIG. 5. As indicated at C1 of FIG. 5, after the MQA has been made active, the signal level of the SA is switched as indicated at C2. In this instance, a short clock pulse (glitch) may be outputted in the SQA, as indicated at C3, depending on the relation between the timing to switch the signal level of the SA and the clock CKA2 after switching. In accordance with the present embodiment, as indicated at C4, the MQA is made inactive at a falling edge of the SQA after the SQA has been switched, whereby the clock can be switched while masking a clock pulse of a short H level, as indicated at C5. It is possible that, if a very short pulse is generated at the time of switching the SQA, a falling edge of the pulse may not be detected. In such a case, as indicated at C6, the MQA is made inactive at the next falling edge of the SQA, whereby the period of masking the CKQA is extended, as indicated at C7. In this manner, according to the present embodiment, even if a falling edge of a pulse at the time of switching the SQA cannot be detected, the clock can be switched without generating a glitch in the CKQA.

With the clock switching circuit of the comparison example described above, one of the clocks to be switched is used to sample the other clock, such that it is difficult to switch among three or more clocks. Also in the comparison example, the frequency of a clock to be used for sampling needs to be two times or greater the frequency of a clock to be sampled, which poses a limitation to the frequency ratio of clocks to be switched.

In contrast, in accordance with the present embodiment, the mask signal generation circuit 30 may sample the clock switching signal CKSA based on the output clock CKQA or a delay clock of the output clock CKQA, thereby causing the mask signal MQA to be active.

In accordance with the present embodiment, the mask signal generation circuit 30 can generate a mask signal MQA and a select signal SA based on a selected clock SQA and an output clock CKQA. With this, the MQA and the SA can be generated without sampling one of the clocks to be switched with the other clock. In this manner, switching among desired clocks of three or more clocks can be realized without a restriction to the frequency ratio of clocks to be switched.

Furthermore, in accordance with the present embodiment, by sampling the clock switching signal CKSA based on the output clock CKQA or a delay clock of the output clock CKQA, the mask signal MQA can be made active after an edge of the output clock CKQA or the delay clock of the output clock CKQA has been outputted (after a change in the signal level). With this, at the time of switching the SQA, the clock can be switched without forming the clock pulse of the clock CKA1 prior to the switching into a fractional clock pulse. For example, as described with reference to FIG. 4, when the MQA is made active at a falling edge of the SQA, a clock pulse at H level of the clock CKA1 prior to switching is outputted, and the SQA is switched after the CKA1 changes to L level. Then, the MQA is made inactive at a falling edge of the clock CK2 after the switching, and the mask is released when the CKA2 is at L level. By so doing, as the CKQA, L level of the CKA1 prior to the start of a masking period, L level during the masking period, and L level of the CKA2 after the end of the masking period are outputted. Therefore, the clock CKA1 can be switched to the clock CKA2 without its clock pulse at H level prior to switching being formed into a fractional clock pulse.

Furthermore, in accordance with the present embodiment, the mask signal generation circuit 30 may output the select signal SA based on a signal that is obtained by delaying a signal generated through sampling the clock switching signal CKSA based on the output clock CKQA or a delay clock of the output clock CKQA.

With this, the signal level of the select signal SA can be switched after the mask signal MQA has been made active. Specifically, as described above, the mask signal MQA is made active through sampling the clock switching signal CKSA based on the output clock CKQA or a delay clock of the output clock CKQA. Therefore, by outputting the SA based on a signal that is obtained by delaying a signal generated through sampling the CKSA based on the CKQA or a delay clock of the CKQA, the SA can be switched at a timing later than the timing at which the MQA is made active. In this manner, the clock can be switched during a masking period.

### 2.3. First Detailed Composition Example

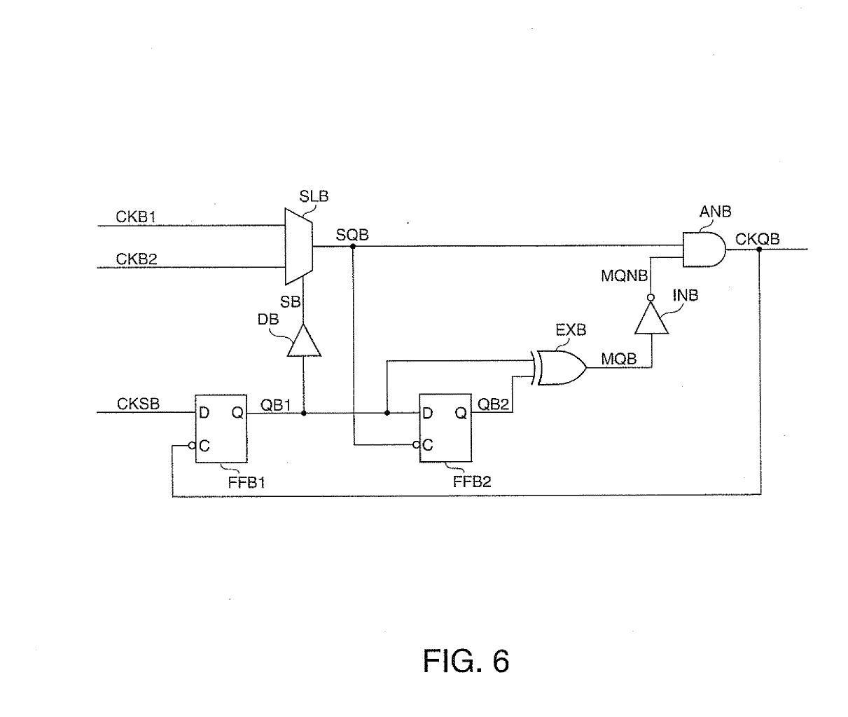

FIG. 6 shows a first detailed composition example of the clock switching circuit in accordance with an embodiment of the invention. The clock switching circuit shown in FIG. 6 includes a selector SLB, an AND circuit ANB, an inverter INB (an inversion logic circuit), first and second flip-flop circuits FFB1 and FFB2, an exclusive OR circuit EXB, and a delay circuit DB. The clock switching circuit is a circuit that switches among first and second clocks CKB1 and CKB2 as plural clocks without generating a glitch. It is noted that the clock switching circuit according to the invention is not limited to the composition shown in FIG. 6, and many modifications, such as, omission of a part of the components (for example, the delay circuit DB), addition of other components (for example, addition of a logic circuit between the ANB and the FFB1) and the like can be made.

The selector SLB selects either of the CKB1 and CKB2 based on a select signal SB from the delay circuit DB, and outputs a selected clock SQB. For example, the SLB selects the CKB1 when the SB is at L level, and selects the CKB2 when the SB is at H level. For example, the SLB may be composed of transfer gates with CMOS transistors, whereby one of the clocks may be selected by turning on one of the transfer gates corresponding to a clock to be selected. Alternatively, the SLB may be comprised of clock inverters, whereby one of the clocks may be selected by setting one of the clocked inverters corresponding to a clock to be selected to be in an output enable state.

The flip-flop circuit FFB1 latches (samples) a clock switching signal CKSB2 at a falling edge of the output clock CKQB, and outputs a first output signal QB1. The flip-flop circuit FFB2 latches (samples) the QB1 at a falling edge of a selected clock SQB, and outputs a second output signal QB2. The delay circuit DB delays the QB1, and outputs the delayed QB1 as the SB. For example, the DB may be comprised of a logic circuit such as a circuit of an even number of serially connected inverters, or may be comprised of an RC delay circuit with which a delay time is set by a RC circuit. The exclusive OR circuit EXB obtains an exclusive OR of the QB1 and QB2, and outputs a mask signal MQB. Specifically, the EXB causes the MQB to be H level, when the QB1 is at L level and the QB2 is at H level, or when the QB1 is at H level and the QB2 is at L level.

The inverter INB inverts the logic level of the mask signal MQB, and outputs a signal MQNB. In other words, the INB outputs the MQNB at H level when the MQB is at L level, and outputs the MQNB at L level when the MQB is at H level. The AND circuit ANB obtains a logical product of the selected clock SQB and the signal MQNB, and outputs an output clock CKQB. Specifically, the ANB outputs the CKQB at L level when the MQNB is at L level thereby masking the SQB, and outputs the SQB as the CKQB when the MQNB is at H level.

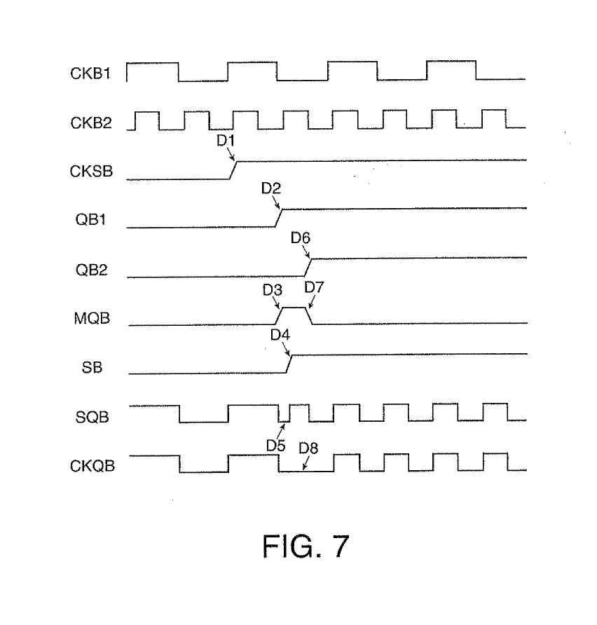

FIG. 7 shows an example of signal waveforms of the clock switching circuit in accordance with the first detailed composition example. As indicated at D1 in FIG. 7, as the CKSB is changed from L level to H level (or H level to L level), the CKSB is latched at a falling edge of the CKQB, and the QB1 is changed from L level to H level, as indicated at D2. As indicated at D3, the MQB is changed from L level to H level. As indicated at D4, the QB1 is delayed and the SB is changed from L level to H level. As indicated at D5, the SQB is switched from the CKB1 to the CKB2. As indicated at D6, the QB1 is latched at a falling edge of the SQB, and the QB2 is changed from L level to H level. As indicated at D7, the MQB is changed from H level to L level. Then, as the CKQB at L level is outputted during the period in which the MQB is at H level, the SQB is masked, and the CKQB is switched from the CKB1 to the CKB2, as indicated at D8.

In accordance with the present embodiment, as the FFB1 latches the CKSB at a falling edge of the CKQB and outputs the QB1, the clock switching signal CKSB can be sampled based on the output clock CKQB. Also, in accordance with the present embodiment, the EXB causes the MQB to be active when the signal level of the QB1 changes, and the DB delays the change in the signal level of the QB1 thereby changing the signal level of the SB. By this, the signal level of the select signal SB can be switched after the mask signal MQB has been made active. In accordance with the present embodiment, as the FFB2 latches the QB1 at a falling edge of the SQB, a change in the signal level of the selected clock SQB can be detected. Then, as the EXB makes the MQB inactive when the signal level of the QB2 changes, the mask signal MQB can be made inactive on condition that a change in the signal level of the selected clock SQB is detected. In accordance with the present embodiment, as the DB delays a change in the signal level of the QB1 to change the signal level of the SB, the select signal SB can be outputted based on the signal that is obtained by delaying the signal QB1 generated through sampling the clock switching signal CKSB based on the output clock CKQB. In this manner, in accordance with the present embodiment, the first and second clocks CKB1 and CKB2 can be switched without generating a glitch.

### 2.4. Second Detailed Composition Example

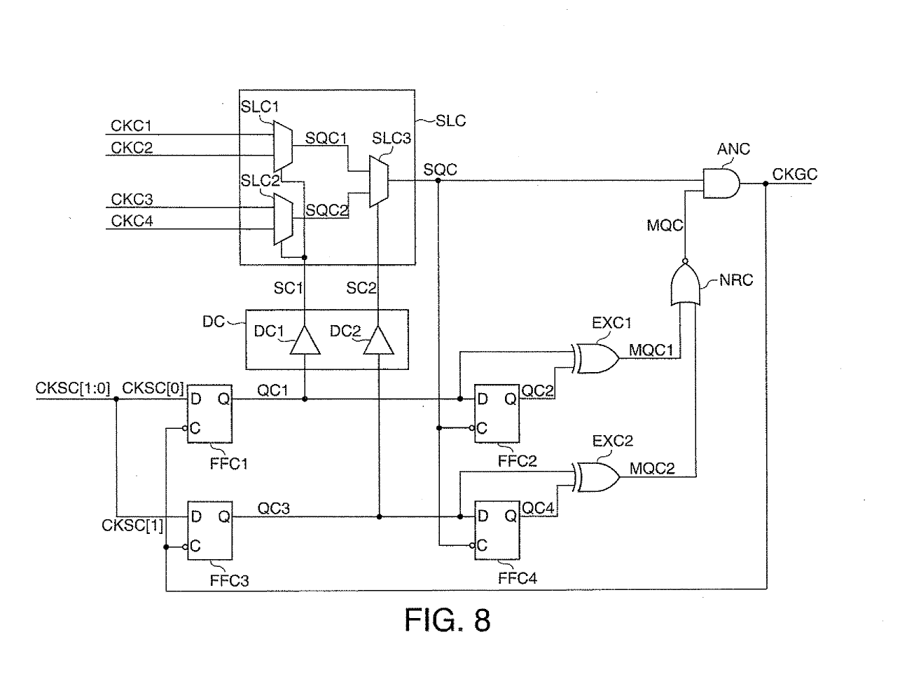

FIG. 8 shows a second detailed composition example of the clock switching circuit in accordance with an embodiment of the invention. The clock switching circuit shown in FIG. 8 includes a selector SLC, an AND circuit ANC, a mask signal output circuit NRC, first through fourth flip-flop circuits FFC1 through FFC4, first and second exclusive OR circuits EXC1 and EXC2, and a delay circuit DC. The clock switching circuit is a circuit that switches among first through fourth clocks CKC1-CKC4 as plural clocks without generating a glitch. It is noted that the clock switching circuit according to the invention is not limited to the composition shown in FIG. 8, and many modifications, such as, omission of a part of the components (for example, the delay circuit DC), addition of other components (for example, addition of a logic circuit between the ANC and the FFC1 and FFC2) and the like can be made.

The selector SLC selects one of the CKC1 CKC4 based on select signals SC1 and SC2 from the delay circuit DC, and outputs a selected clock SQC. Specifically, the SLC includes selectors SLC1 through SLC3. The SLC1 selects one of the CKC1 and the CKC2 based on the SC1, and outputs a clock SQC1. The SLC2 selects one of the CKC3 and CKC4 based on the SC1, and outputs a clock SQC2. The SLC3 selects one of the SQC1 and the SQC2, and outputs a selected clock SQC. For example, the SLC selects CKC1, CKC2, CKC3 and CKC4 according to (SC1, SC2) being (0, 0), (1, 0), (0, 1) and (1, 1), respectively, where 0 is L level and 1 is H level.

The flip-flop circuit FFC1 latches a clock switching signal CKSC [0] of clock switching signals CKSC [1:0] at a falling edge of the output clock CKQC, and outputs a first output signal QC1. The flip-flop circuit FFC2 latches the QC1 at a falling edge of the selected clock SQC, and outputs a second output signal QC2. The flip-flop circuit FFC3 latches the clock switching signal CKSC [1] of the clock switching signals CKSC [1:0] at a falling edge of the output clock CKQC, and outputs a third output signal QC3. The flip-flop circuit FFC4 latches the QC3 at a falling edge of the selected clock SQC, and outputs a fourth output signal QC4. The delay circuit DC delays the output signals QC1 and QC3, and outputs select signals SC1 and SC2. More specifically, the DC includes first and second delay circuits DC1 and DC2. The DC1 delays the QC1, and outputs the delayed QC1 as the SC1, and the DC2 delays the QC3, and outputs the delayed QC3 as the SC2. The exclusive OR circuit EXC1 obtains an exclusive OR of the QC1 and QC2, and outputs a first mask signal MQC1. The exclusive OR circuit EXC2 obtains an exclusive OR of the QC3 and the QC4, and outputs a second mask signal MQC2. The mask signal output circuit NRC (an inversion OR circuit, a NOR circuit) obtains an inverted OR of the MQC1 and the MQC2, and outputs a mask signal MQC. In other words, the NRC outputs the MQC at H level in the case where the MQC1 and the MQC2 are at L level, and outputs the MQC at L level in other cases.

The AND circuit ANC obtains a logical product of the selected clock SQC and the mask signal MQC, and outputs the output clock CKQC. Specifically, the ANC outputs the CKQC at L level when the MQC is at L level thereby masking the SQC, and outputs the SQC as the CKQC when the MQC is at H level.

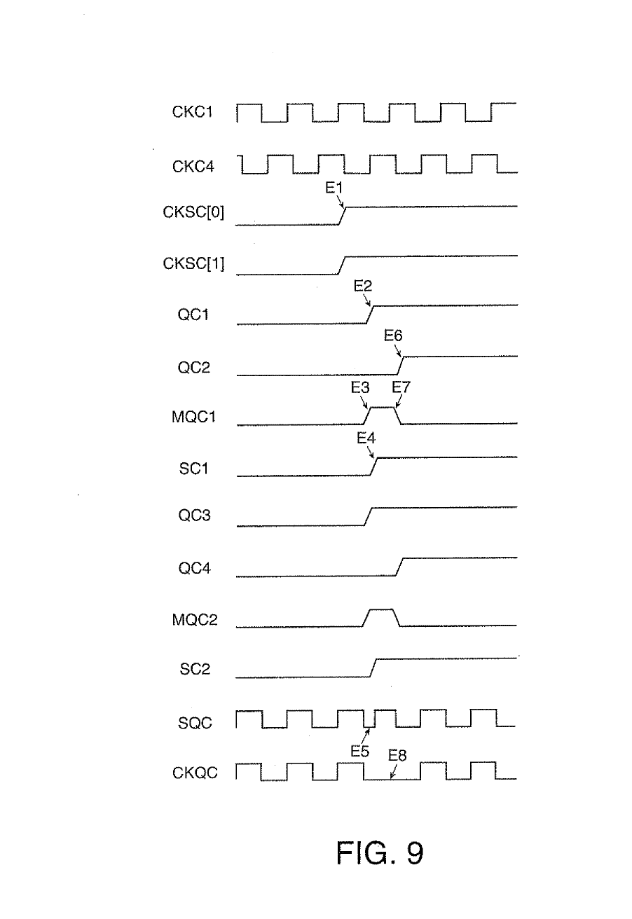

FIG. 9 shows an example of signal waveforms of the clock switching circuit in accordance with the second detailed composition example. It is noted that FIG. 9 shows an example of signal waveforms when changing, among clocks CKC1-CKC4, the CKC1 to the CKC4, and omits an example of signal waveforms of the CKC2 and CKC3.

As indicated at E1 in FIG. 9, when the CKSC [0] is changed from L level to H level (or from H level to L level), the CKSC [0] is latched at a falling edge of the CKQC, whereby the QC1 is changed from L level to H level, as indicated at E2. As indicated at E3, the MQC1 is changed from L level to H level. As indicated at E4, the QC1 is delayed, and the SC1 is changed from L level to H level. Likewise, when the CKSC [1] is changed from L level to H level (or from H level to L level), the QC3 is changed from L level to H level, the MQC2 is changed from L level to H level, and the SC2 is changed from L level to H level. Then, as indicated at E5, the SQC is switched from the CKC1 to the CKC4. As indicated at E6, the QC1 is latched at a falling edge of the SQC, whereby the QC2 is changed from L level to H level. As indicated at E7, the MQC1 is changed from H level to L level. Likewise, the QC4 is changed from L level to H level, and the MQC2 is changed from H level to L level. Then, as indicated at E8, the CKQC at L level is outputted during the period in which the MQC1 and the MQC2 (at least one of the MQC1 and the MQC2) are at H level thereby masking the SQC, and the CKQC is switched from the CKC1 to the CKC4.

In accordance with the embodiment described above, switching between desired ones of the first through fourth clocks CKC1-CKC4 can be performed without generating a glitch. It is noted that the second detailed composition example has been described with reference to a composition example for switching among the first through fourth clocks CKC1-CKC4, as a plurality of clocks. However, in accordance with the invention, first through third clocks as a plurality of clocks may be switched. For example, in the second detailed composition example shown in FIG. 8, the selector may selects among first through third clocks CKC1-CKC3. Specifically, the SLC may include SLC1, SLC2 and SLC3, the SLC1 may select one of the CKC1 and the CKC2 to output the SQC1, and the SLC3 may select one of the SQC1 and the CKC3 to output the SQC.

### 3. Integrated Circuit Device

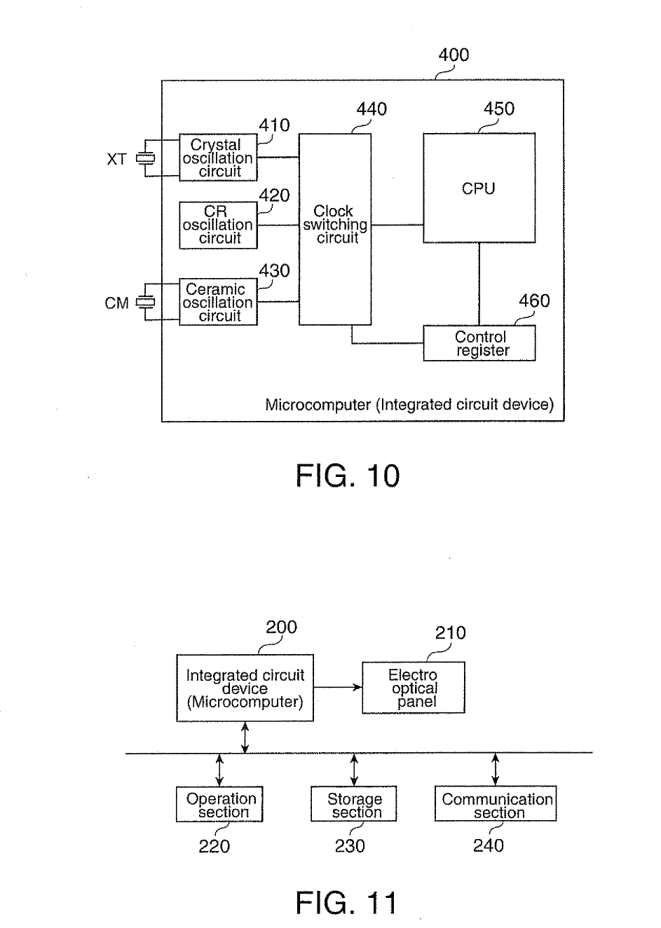

FIG. 10 shows a composition example of an integrated circuit device that includes a clock switching circuit 440 in accordance with an embodiment of the invention. FIG. 10 shows a composition example of a microcomputer 400 as the composition example of an integrated circuit device. It is noted that the clock switching circuit according to the invention is also applicable to other integrated circuit devices such as ASICs for sensors, communication devices, AV devices and the like.

The microcomputer 400 shown in FIG. 10 includes a crystal oscillation circuit 410, a CR oscillation circuit 420 (a built-in clock generation circuit), a ceramic oscillation circuit 430, a clock switching circuit 440, a CPU 450 and a control register 460.

The crystal oscillation circuit 410 generates a clock, using oscillation of a crystal vibrator XT. The CR oscillation circuit 420 is formed from, for example, a ring oscillator that is fed back with a CR circuit, and generates a clock with a frequency set by the capacitance value and the resistance value of the CR circuit. The ceramic oscillation circuit 430 generates a clock, using oscillation of a ceramic oscillator CM. The clock switching circuit 440 selects one of the clocks from the oscillator circuits, and supplies a selected one of the clocks to the CPU 450. The CPU 450 executes a variety of operation processings using the clocks from the clock switching circuit 440. Register values for controlling the microcomputer 400 are written to the control register 460 by the CPU 450, Register values for controlling clock switching are written to the control register 460, and the resister values are supplied as clock switching signals to the clock switching circuit 440.

### 4. Electronic Apparatus

FIG. 11 shows a composition example of an electronic apparatus including an integrated circuit device 200 in accordance with an embodiment of the invention. The electronic apparatus includes the integrated circuit device 200, an electro optical panel 210, an operation section 220, a storage section 230, and a communication section 240. It is noted that it is possible to make many modifications including omission of a part of the above components, addition of other components and the like.

The integrated circuit device 200 may be, for example, a microcomputer, and may control the electro optical panel 210, and execute a variety of operation processings necessary for operation of an electronic apparatus. The electro optical panel 210 is provided for displaying various images, and may be realized with, for example, an LCD (liquid crystal display) or the like. The operation section 220 allows the user to input a variety of information, and may be realized with a variety of buttons, a keyboard and the like. The storage section 230 stores a variety of data, and may be realized with a RAM, a ROM and the like. The communication section 240 performs processings for communication with an external device, and may be realized with an ASIC for wireless or wired communication.

As the electronic apparatuses realized by the present embodiment, a variety of apparatuses, such as, clocks, remote controllers, portable information terminals, cellular phones, a variety of home appliances and the like can be enumerated.

It is noted that, although some embodiments of the invention have been described in detail above, those skilled in the art would readily appreciate that many modifications are possible without departing in substance from the novel matter and effects of the invention. Accordingly, such modifications are deemed to be included within the scope of the invention. For example, throughout the specification and the drawings, any terms (active, inactive, microcomputer and the like) described at least once with other different terms (first logical level, second logical level, integrated circuit device and the like) that encompass broader meaning or are synonymous can be replaced with these different terms in any sections of the specification and the drawings. Also, the structures and operations of the mask signal generation circuit, the mask circuit, the clock switching circuit, the integrated circuit device, the electronic apparatus and the like are not limited to those described in the present embodiments, and many modifications can be made.

What is claimed is:

1. A clock switching circuit comprising:
a selector that selects one of a plurality of clocks based on a select signal and outputs the clock selected as a selected clock;
a mask circuit that masks the selected clock based on a mask signal and outputs the selected clock masked as an output clock; and
a mask signal generation circuit that generates the mask signal and the select signal,
the mask signal generation circuit switching a signal level of the select signal after causing the mask signal to be active, and causes the mask signal to be inactive on condition that a change is detected in the signal level of the selected clock after the signal level of the select signal has been switched.

2. A clock switching circuit according to claim 1, the mask signal generation circuit causing the mask signal to be active through sampling a clock switching signal based on the output clock or a delay clock of the output clock.

3. A clock switching circuit according to claim 2, the mask signal generation circuit outputting the select signal based on a signal obtained by delaying a signal that is generated through sampling the clock switching signal based on the output clock or the delay clock of the output clock.

4. A clock switching circuit according to claim 1, the mask signal generation circuit including:
a first flip-flop circuit that samples the clock switching signal based on the output clock or a delay clock of the output clock and outputs a first output signal;
a second flip-flop circuit that samples the first output signal based on the selected clock and outputs a second output signal; and
an exclusive OR circuit that obtains an exclusive OR of the first output signal and the second output signal and outputs the mask signal,
the selector receiving the select signal based on the first output signal and selects one of a first clock and a second clock among the plurality of clocks.

5. A clock switching circuit according to claim 4, the mask signal generation circuit including a delay circuit that receives the first output signal from the first flip-flop circuit and outputs the select signal.

6. A clock switching circuit according to claim 1, the mask signal generation circuit including:
a first flip-flop circuit that samples the clock switching signal based on the output clock or the delay clock of the output clock and outputs a first output signal;
a second flip-flop circuit that samples the first output signal based on the selected clock and outputs a second output signal;
a first exclusive OR circuit that obtains an exclusive OR of the first output signal and the second output signal and outputs a first mask signal;
a third flip-flop circuit that samples the clock switching signal based on the output clock or a delay clock of the output clock and outputs a third output signal;
a fourth flip-flop circuit that samples the third output signal based on the selected clock and outputs a fourth output signal;
a second exclusive OR circuit that obtains an exclusive OR of the third output signal and the fourth output signal and outputs a second mask signal; and
a mask signal output circuit that outputs the mask signal based on the first mask signal and the second mask signal,
the selector receiving the select signal based on the first output signal and the third output signal and selects one of a first clock through a fourth clock among the plurality of clocks.

7. A clock switching circuit according to claim 6, the mask signal generation circuit including a delay circuit that outputs the select signal upon receiving the first output signal from the first flip-flop circuit and the third output signal from the third flip-flop circuit.

8. An integrated circuit device comprising the clock switching circuit recited in claim 1.

9. An electronic apparatus comprising the integrated circuit device recited in claim 8.
